(19) United States
(12) Patent Application Publication
(10) Pub. No.: US 2010/0189883 A1
(43) Pub. Date: Jul. 29, 2010

(54) CONTINUOUS PROCESS FOR PREPARING AND COLLECTING NANOTUBE FILMS THAT ARE SUPPORTED BY A SUBSTRATE

(76) Inventor: Martin Pick, Yorkshire (GB)

Correspondence Address: Thomas M. Galgano, 20 W. Park Avenue, Suite 204, Long Beach, NY, 11561, US

(21) Appl. No.: 12/597,830

(22) PCT Filed: Apr. 28, 2008
(86) PCT No.: PCT/GB08/01461

§ 371 Date: Apr. 2, 2010

(30) Foreign Application Priority Data
Apr. 28, 2007 (GB) 0708294.4

(51) Int. Cl. C23C 16/26

(52) U.S. Cl. 427/109; 977/742; 977/932

(57) ABSTRACT

A continuous process whereby carbon nanotubes, usually in the form of an aerogel are harvested from a high temperature reactor by means of an adhesive substrate that is passed across an outlet port at a predetermined rate whereby the carbon nanotube aerogel is fixed and transported away from the reactor and associated apparatus for suitable storage.

The described invention relates to the harvesting of carbon nanotubes, preferably in the form of an aerogel, grown in a high temperature Chemical Vapour Deposition (CVD) reactor. The harvesting is accomplished by depositing the nanotube aerogel continuously or discontinuously on a moving tape or other substrate.

The aforementioned reactor is preferably an elongated glass tube exampled by a tube of 90 millimetres diameter and 1.5 metres long. When in operation the reactor contains flammable gases and artefacts maintained at a high temperature. It is necessary to provide a purpose built harvesting chamber at the output end of the reactor through which the aforementioned aerogel can be withdrawn as it is produced.

The harvesting chamber provided an open-ended channel with no internal structures that allows unimpeded harvesting of carbon nanotube products which is an aerogel in the case of the described invention.

By using a combination of gas flow through the reactor and a continuously moving substrate placed close to the outlet of the aforementioned harvesting chamber at the outlet end of a furnace the continuous deposition and collection of the nanotube aerogel is made possible. The process of passing a substrate near to the outlet of the furnace allows the aerogel to be captured before it forms into a fibre. By controlling the pass speed of the substrate the width and thickness of the aerogel deposition can be altered according to need. Fibre can also be harvested by this means if required.

For the purposes of this invention an aerogel is defined as colloid that has a continuous solid phase containing dispersed gas and a colloid is defined as a mixture having particles with diameters ranging between ten to the minus seven and ten to the minus ninth of a metre.

### PRIOR ART

Production of Agglomerates from Gas Phase. WO/2005/007926

Cambridge University Technical Services Ltd. Kinloch et al.

Continuous Deposition of Carbon Nanotubes Under open Air Conditions on a Moving Fused Quartz Substrate Using Pyrolytic CVD.

Journal: Carbon 2005 Vol. 43 No. 12 pp 2571-2578 Dept. of Mechanical Engineering, University of Connecticut. Kwok et al.

Thin Film Production Method and Apparatus. WO/2006/099156

App. Tailored Material Corporation.

Inventors: Loutfy et al.

Priority Date. Mar. 10, 2005

Production of Agglomerates from Gas Phase. WO/2005/007926

A. This application discloses the method and form of the production of an aerosol of carbon nanotubes from Gas phase in a suitable reactor.

B. Continuous Deposition of Carbon Nanotubes Under open Air Conditions on a Moving Fused Quartz Substrate Using. Pyrolytic CVD.

Journal: Carbon 2005 Vol. 43 No. 12 pp 2571-2578 Dept. of Mechanical Engineering, University of Connecticut. Kwok et al.

This disclosure does not conflict with the invention herein described as the nanotubes are not in an aerogel form and are caused to settle on the substrate using a vacuum which draws reaction gas through the substrate.

C. Thin Film Production Method and Apparatus. WO/2006/099156

App. Tailored Material Corporation.

Inventors: Loutfy et al.

Priority Date. Mar. 10, 2005

Once again this disclosure does not conflict with the described invention as the nanotubes are not in aerogel form.

The process for preparing the carbon nanotubes is derived from Patent WO2005007926, which disclosed a process for preparing continuous fibers of carbon nanotubes from the gas phase using a chemical vapor deposition (CVD) process. Briefly, this involves injecting an appropriate reaction mixture into a reactor tube that is maintained at a temperature of at least 1100° C. using a carrier gas to drive the reaction mixture through the reactor tube. In addition to the carrier gas, the reaction mixture consists of a hydrocarbon feedstock, a soluble or volatile metal-containing catalyst precursor, and a sulphur-containing species that behaves as a growth promoter. The nanotubes are produced as an aerogel.

The described invention uses a substrate which is preferably in the form of a tape or ribbon which can be impervious or porous. The tape or ribbon contained on a spool, is unwound, passes near the outlet of the aforementioned furnace and is rewound on a take-up reel. The tape captures the nanotubes produced as described above mechanically drawing the aerogel from the reactor. The tape and its captured nanotubes are wound onto a suitable spool and can be unwound when needed.

According to the described invention there is provided a reactor consisting a ceramic tube which, for example only can be 1.5 metres long and 90 mm in diameter. In the preferred example of use the reactor is heated to 1180° C. using a tube furnace. The top of the mullite tube is equipped with appropriate stainless steel fittings that allow the simultaneous injection of a carrier gas while excluding the ambient atmosphere from the reaction zone. The bottom of the reactor tube is equipped with a “Gas-exchange valve” as described in PCT Patent Application GB2006/001/001.

The aerogel of CNTs is collected onto the adhesive side of tape exampled by Scotch® “Magic Tape” and Scotch “Crystal Clear Tape”. Each was each used as the substrate. These substrates were as-prepared by the 3M Corporation.

An example of a solution was prepared that contained 1.8% (wt/wt) ferrocene, 0.4% (wt/wt) thiophene, and 97.8% (wt/wt) absolute ethanol (>99.9% ethanol). The mixture was filtered through a 25 micron syringe filter to remove non-dissolved particles of ferrocene. The filtered reaction mixture was de-gassed by placing it in a bottle under vacuum and immersing the bottle in an ultrasonic bath.

The reaction tube is first purged with argon to remove the air and then with hydrogen at a flow rate of 2 L/min for at least 10 minutes prior to beginning the reaction. While maintaining a fixed hydrogen injection rate through the top of the furnace (either 1.5 L/min or 2.25 L/min, as noted below), the reaction mixture is injected into the top of the furnace at a rate of 0.1 ml/minute using a high pressure, liquid chromatography (HPLC) pump.

The reaction can be monitored visually through the use of a mirror to look through the gas-valve and up into the reaction zone. After injecting the reaction mixture for several minutes, the aerogel will appear as a dark cloud, which is generally cylindrical in shape. The aerogel cylinder (referred to as a sock) is extracted through the gas-exchange valve from the reaction zone using a long, stainless steel rod.

The aerogel is deposited onto the adhesive side of the tape, nearest to the top of a collection reel. Initially the take-up reel is at rest. The wind-up of the tape begins as the take-up reel is slowly accelerated using its motor drive. The aerogel is monitored as it leaves the bottom of the gas valve, and the wind-up motor is accelerated until the width of the aerogel decreases due to its elongation. The winding rate of the take-up reel can be decreased until it reaches a rate such that the aerogel maintains a constant and stable width that spans the desired width of the tape (typically between 1 to 2 cm). When this occurs the windup is maintained at a constant rate until the supply of tape is exhausted. Adhesion to tape not provided with an adhesive can be provided by electrostatic, magnetic or other means or if required.

Samples are prepared for electrical sheet resistance measurements by masking a well-defined region with a glass slide and coating the exposing areas of the film with a thin layer (approximately 50 nm) of gold by sputtering. The resistance across the gold electrodes is determined using a Fluke 27 Mulitmeter.

The transparency of the films is determined with a Uvikon 860 double-beam spectrophotometer (Kontron Instruments) at a fixed wavelength of 550 nm, using the corresponding tape substrate (without CNTs present) as a reference.

Using a hydrogen flow rate of 1.5 L/min during injection and Scotch® “Magic Tape” as a substrate, samples were obtained that transmitted 94% visible light at 550 nm, and exhibited a DC sheet resistance of 2.59 kiloOhms/square.

A sample prepared using a hydrogen flow rate of m2.5L/min and Scotch Crystal Clear Tape exhibited a DC resistance of 40 Kilo ohms/Square and transmitted 97% light at 550 nms.

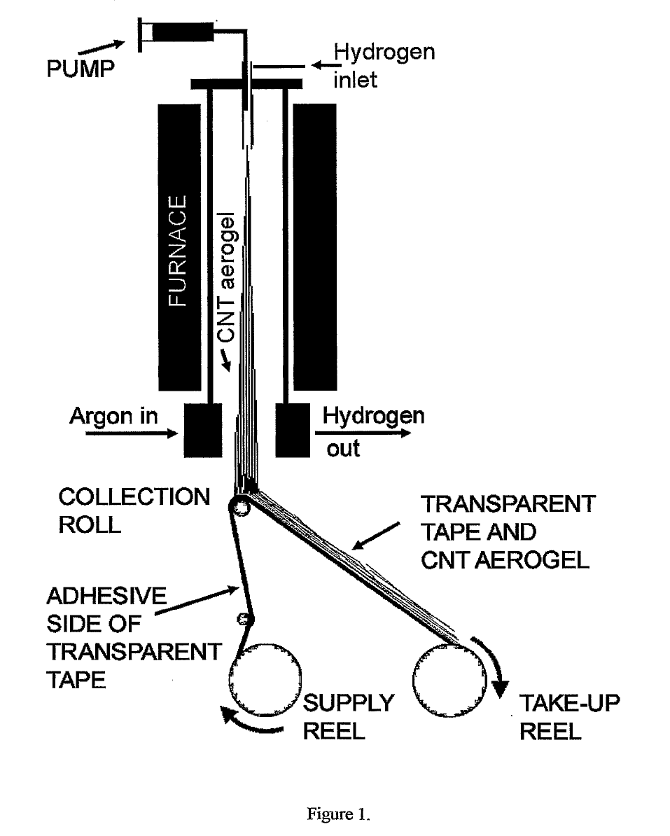

Detailed description will be made with reference to FIG. 1.

With reference to FIG. 1.
The schematic shown indicates the HPLC pump which injects the feedstock into the reaction vessel via the hydrogen inlet as shown.
The reaction vessel is heated by the furnace as shown.
Argon in/hydrogen out indicates the operation of the gas isolation/exchange valve.
The aerogel sock is indicated within the reaction vessel.
The aerogel sock is shown being taken up by the travelling tape on its adhesive side.
Driven take up reel and passive supply reel are shown.

It is understood that the description with reference to FIG. 1 is for example only.

The principle motivation for this invention is the provision of transparent conductors that can be used as anti-static packaging materials, as shielding against electromagnetic interference (EMI), as transparent electrodes in electronic devices and any application to which the properties of aerogel/tape substrate can be applied. Examples of such applications are electro-optical cells for the generation of electricity from sunlight, liquid crystal displays, plasma displays, touch-sensitive displays, and electroluminescent displays. In any eSm St Cashbodiment of the invention, the preferred form of the substrate is a transparent polymer.

In other embodiments of this invention, optical transparency may be a less important property. For example, the invention may be used to impart electrical conductivity to tapes or ribbons that are initially electrically insulating or the carbon nanotube layer deposited onto the tape or ribbon may be used to provide mechanical reinforcement. These embodiments may also use a polymer substrate (which may or may not be transparent), but other suitable substrates include paper, cloth, ceramic, metal ribbons, and composite materials.

1. A process for depositing an aerogel of carbon nanotubes directly on a substrate, comprising the steps of:
passing the substrate continuously across an outlet of a reactor in which a nanotube aerogel is prepared.

2. The process according to claim 1, wherein:
the substrate is passed discontinuously across the outlet of the reactor in which the carbon nanotube aerogel is prepared through the variation of rate of the moving substrate.

3. The process according to claim 1, wherein:
the coated substrate is transparent to electromagnetic radiation.

4. The process in according to claim 1, wherein:
the coated substrate is transparent to specific wavelengths of electromagnetic radiation.

5. The process according to claim 1, wherein:
the coated substrate is opaque to electromagnetic radiation.

6. The process according to claim 1, wherein:
the electrical properties of the substrate are modified when coated with nanotubes.

7. The process according to claim 1, wherein:
the thermal properties of the substrate are modified.

8. The process according to claim 1, wherein:
the mechanical properties of the substrate are modified.

9. (canceled)

10. The process according to claim 2, wherein:
the coated substrate is transparent to electromagnetic radiation.

11. The process according to claim 2, wherein:
the coated substrate is transparent to specific wavelengths of electromagnetic radiation.

12. The process according to claim 3, wherein:
the coated substrate is transparent to specific wavelengths of electromagnetic radiation.

13. The process according to claim 4, wherein:
the coated substrate is transparent to specific wavelengths of electromagnetic radiation.

14. The process according to claim 2, wherein:
the coated substrate is opaque to electromagnetic radiation.

15. The process according to claim 3, wherein:
the coated substrate is opaque to electromagnetic radiation.

16. The process according to claim 2, wherein:
the electrical properties of the substrate are modified when coated with nanotubes.

17. The process according to claim 3, wherein:
the electrical properties of the substrate are modified when coated with nanotubes.

18. The process according to claim 2, wherein:
the thermal properties of the substrate are modified.

19. The process according to claim 3, wherein:
the thermal properties of the substrate are modified.

20. The process according to claim 2, wherein:
the mechanical properties of the substrate are modified.

21. The process according to claim 3, wherein:
the mechanical properties of the substrate are modified.
